(19) United States
(12) Patent Application Publication
(10) Pub. No.: US 2025/0361432 A1
(43) Pub. Date: Nov. 27, 2025

(54) Slurry Composition for Chemical Mechanical Polishing

(71) Applicant: KCTECH CO., LTD., Gyeonggi-do (KR)

(72) Inventors: Seul Ki KIM, Gyeonggi-do (KR); Ye Sol KANG, Gyeonggi-do (KR); Jin Hyun CHOI, Seoul (KR); Han Bit PARK, Daejeon (KR)

(21) Appl. No.: 19/215,593

(22) Filed: May 22, 2025

(30) Foreign Application Priority Data
May 23, 2024 (KR) 10-2024-0067044

(51) Int. Cl. C09K 3/14

(52) U.S. Cl. CPC C09K 3/1454; C09K 3/1436

(57) ABSTRACT

Provided is a chemical mechanical polishing (CMP) slurry composition. The CMP slurry composition includes abrasive particles, a chelating agent, an oxidizing agent, and a corrosion inhibitor, and the abrasive particles are core-shell type particles in which a core is a polymethyl methacrylate (PMMA) polymer and a surface of the core is coated with inorganic oxide.

### CROSS-REFERENCE TO RELATED APPLICATION

This application claims the benefit of Korean Patent Application No. 10-2024-0067044 filed on May 23, 2024, in the Korean Intellectual Property Office, the entire disclosure of which is incorporated herein by reference for all purposes.

### BACKGROUND

### 1. Field of the Invention

One or more embodiments relate to a slurry composition for chemical mechanical polishing (CMP) including core-shell abrasive particles in which a core is a polymethyl methacrylate (PMMA) polymer.

### 2. Description of the Related Art

A chemical mechanical polishing (CMP) process is a process of performing planarizing using a polishing pad and a slurry composition during the manufacturing of semiconductors and the like, by injecting a slurry containing abrasive particles onto a substrate and using a polishing pad mounted on a polishing device. In this case, the abrasive particles receive pressure from the polishing device to polish the surface mechanically, and chemical components contained in the polishing slurry composition cause a chemical reaction on the surface of the substrate to chemically remove a surface area of the substrate.

In general, there are various types of polishing slurry compositions depending on the type and characteristics of a target to be removed. Among these, in the process of polishing a specific metal layer, particularly, a copper (Cu) layer that is widely used for metal wiring, surface defects such as scratches, erosion, and dishing are more noticeable than in other metals. Therefore, a copper film polishing slurry composition that may achieve a low level of surface defects along with an appropriate polishing rate is required. If not, the polishing process time may be extended, which may result in a decrease in process yield, or the semiconductor yield and stability may be reduced due to a copper layer curvature or residual copper layer generation, and short circuits between copper wiring layers may occur, which may cause device defects.

### SUMMARY

Example embodiments provide a chemical mechanical polishing (CMP) slurry composition that may improve pattern characteristics of a metal film by minimizing defects such as scratches, dishing, and corrosion on a surface of a final polishing target film while achieving a desired polishing rate in polishing a metal film, particularly a copper film.

However, technical goals to be achieved are not limited to those described above, and other goals not mentioned above can be clearly understood by one of ordinary skill in the art from the following description.

According to an aspect, there is provided a CMP slurry composition including abrasive particles, a chelating agent, an oxidizing agent, and a corrosion inhibitor, wherein the abrasive particles are core-shell type particles in which a core is a polymethyl methacrylate (PMMA) polymer and a surface of the core is coated with inorganic oxide.

Additional aspects of example embodiments will be set forth in part in the description which follows and, in part, will be apparent from the description, or may be learned by practice of the disclosure.

According to example embodiments, the present disclosure may provide a CMP slurry composition that may reduce the surface defects such as scratches while achieving an appropriate polishing rate for a metal film, particularly a copper film, by applying core-shell abrasive particles in which a PMMA polymer is a core.

It should be understood that the effects of the present disclosure are not limited to the above-described effects, but are construed as including all effects that can be inferred from the configurations and features described in the following description or claims of the present disclosure.

### DETAILED DESCRIPTION

Hereinafter, embodiments will be described in detail. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In addition, the description of embodiments, detailed description of well-known related structures or functions will be omitted when it is deemed that such description will cause ambiguous interpretation of the present disclosure.

In addition, the terms first, second, A, B, (a), and (b) may be used to describe constituent elements of the embodiments. These terms are used only for the purpose of discriminating one component from another component, and the nature, the sequences, or the orders of the components are not limited by the terms.

A component, which has the same common function as a component included in any one embodiment, will be described by using the same name in other embodiments. Unless disclosed to the contrary, the description of any one embodiment may be applied to other embodiments, and the specific description of the repeated configuration will be omitted.

It will be understood that when a certain part “includes” a certain component, the part does not exclude another component but may further include another component.

One aspect of the present disclosure relates to a chemical mechanical polishing (CMP) slurry composition including abrasive particles, a chelating agent, an oxidizing agent, and a corrosion inhibitor, and the abrasive particles are core-shell type particles in which a core is a polymethyl methacrylate (PMMA) polymer and a surface of the core is coated with inorganic oxide.

The core-shell type abrasive particles are a particle type that may simultaneously adopt the advantages of a core portion and a shell portion coated on the core. In particular, when the core is an organic polymer and the surface thereof is coated with inorganic oxide, the inorganic oxide in direct contact with a target metal film increases a polishing rate due to its own hardness and reactivity with the target metal, and at the same time, the high ductility of the organic core reduces an excessive physical force that may result from the abrasive particles, thereby effectively reducing surface defects (scratches, dishing, erosion, and the like) of the target metal film.

In particular, when the core is PMMA, the strength of the abrasive particles may be increased compared to when a low-strength organic polymer such as polystyrene (PS) is introduced as the core, and thus the effect of further increasing the polishing rate may be obtained within a range that does not reduce surface quality of a polishing target film.

According to an embodiment, the inorganic oxide applied onto the surface of the PMMA core may include at least one selected from the group consisting of silica, ceria, zirconia, alumina, titania, barium titania, germania, mangania, magnesia, and zeolite.

According to an embodiment, the CMP slurry composition may include any suitable amount of abrasive particles, and the CMP slurry composition may include, for example, 0.001 wt % to 30 wt % of the abrasive particles, preferably 0.01 wt % to 10 wt %, more preferably 0.1 wt % to 5 wt %, and most preferably 0.5 wt % to 1 wt % of the abrasive particles with respect to a total weight of the CMP slurry composition. In this case, when the amount of abrasive particles is less than 0.001 wt % in the slurry composition, there is a problem that the polishing rate is greatly reduced, and when the amount thereof exceeds 30 wt %, the number of abrasive particles remaining on the surface of the polishing target film may increase due to an increase in the content of the abrasive particles, and defects such as scratches, dishing, and/or erosion in a polishing target film pattern due to overpolishing may occur.

The chelating agent is a type of polishing accelerator that serves to increase the polishing rate through a chemical reaction that forms a complex compound with metal atoms of a metal film to be polished. According to an embodiment, the chelating agent may include one or more of amino acid and organic acid.

According to an embodiment, the amino acid may include at least one selected from the group consisting of glycine, arginine, lysine, histidine, aspartic acid, glutamic acid, asparagine, glutamine, tyrosine, serine, cysteine, threonine, alanine, β-alanine, proline, tryptophan, methionine, phenylalanine, valine, leucine, and isoleucine.

According to an embodiment, the organic acid may include at least one selected from the group consisting of adipic acid, oxalic acid, tartaric acid, fumaric acid, citric acid, mercaptosuccinic acid, glycolic acid, lactic acid, phthalic acid, ascorbic acid, malic acid, maleic acid, malic acid, propionic acid, tartaric acid, poly-amino acetic acid including ethylenediaminetetraacetic acid (EDTA), iminodiacetic acid (IDA), nitrilotriacetic acid (NTA), pentetic acid, and egtazic acid, and a salt form thereof.

According to an embodiment, the chelating agent may be included in an amount of 0.01 wt % to 5 wt %, more preferably 0.1 wt % to 3 wt %, more preferably 1 wt % to 2 wt %, and most preferably 1.5 wt % to 2 wt %, with respect to the total weight of the CMP slurry composition. In this case, when the content of the chelating agent is less than 0.01 wt % with respect to the weight of the composition, the polishing rate is rarely improved, and when the content thereof exceeds 5 wt %, the surface quality of the polishing target film may rapidly decrease due to scratches caused by excessive polishing acceleration.

The corrosion inhibitor is an ingredient that suppresses corrosion of the polishing target film, particularly, a copper film, and may serve to prevent the deterioration of the surface quality of the copper film, such as excessive corrosion of a specific portion of the copper film and the like.

According to an embodiment, the corrosion inhibitor may be an azole compound, and the azole compound may include two or more nitrogen (N) atoms in a molecular structure. The azole compound is a compound that contains a pentagonal ring in a structural formula, and the pentagonal ring further includes one nitrogen (N) atom and one or more non-carbon elements (mainly nitrogen, sulfur (S), and oxygen (O)). The azole compound is known as a compound having an excellent effect in preventing corrosion on various polishing target films including copper.

According to an embodiment, the corrosion inhibitor may include at least one selected from the group consisting of benzotriazole, 1,2,3-triazole, 1,2,4-triazole, tetrazole, imidazole, benzimidazole, pyrazole, pyrazine, pyrimidine, triazolopyridine, triazolopyrimidine, indazole, 5-methyl benzotriazole, 5-aminotetrazole, 1-alkyl-5-aminotetrazole, 5-hydroxy-tetrazole, 1-alkyl-5-hydroxy-tetrazole, tetrazole-5thiol, 1-H-benzotriazole-5-carboxylic acid, 1,2,3-triazole-3-carboxylic acid, and a combination thereof.

When the corrosion inhibitor is the azole compound, it may include two or more different types of azole compounds. The type, mixing ratio, and the like of the azole compounds used may be appropriately selected and used depending on the type and state of the polishing target film. In particular, when the polishing target film is a copper film, the azole compound may include a combination of 1,2,4-triazole and 5-methyl benzotriazole, and a weight ratio of 1,2,4-triazole to 5-methyl benzotriazole may be 100:1 to 1:1, and more preferably 10:1 to 1:1.

According to an embodiment, the corrosion inhibitor may be included in an amount of 0.01 wt % to 5 wt %, more preferably 0.1 wt % to 3 wt %, and most preferably 0.2 wt % to 1 wt % with respect to the total weight of the CMP slurry composition. In this case, when the content of the corrosion inhibitor is less than 0.01 wt % with respect to the composition, the surface quality of the polishing target film after polishing may decrease due to surface defects such as scratches and dishing, and when the content thereof exceeds 5 wt %, the polishing rate may decrease excessively.

The CMP slurry composition may further include a pH adjuster to have an optimal pH for further improving the effect of improving the polishing rate and surface quality.

According to an embodiment, the pH adjuster may include at least one selected from the group consisting of an acidic substance including at least one selected from the group consisting of hydrochloric acid, phosphoric acid, nitric acid, sulfuric acid, hydrofluoric acid, hydrobromic acid, iodic acid, formic acid, malonic acid, maleic acid, oxalic acid, acetic acid, adipic acid, citric acid, propionic acid, fumaric acid, lactic acid, salicylic acid, pimelic acid, benzoic acid, succinic acid, phthalic acid, butyric acid, glutaric acid, glutamic acid, glycolic acid, aspartic acid, tartaric acid, and a salt thereof, and a basic substance including at least one selected from the group consisting of ammonia, ammonium methyl propanol (AMP), tetra methyl ammonium hydroxide (TMAH), ammonium hydroxide, potassium hydroxide, sodium hydroxide, magnesium hydroxide, rubidium hydroxide, cesium hydroxide, sodium bicarbonate, sodium carbonate, and imidazole.

According to an embodiment, the pH of the CMP slurry composition may be 1 to 12, more preferably 5 to 9, and most preferably 6 to 8. When the pH of the composition is less than 5 or more than 9, the unique effect of each component may be reduced due to changes in the composition, such as the abrasive particles, the chelating agent, and corrosion inhibitor, and the charge state of the polishing target film. In particular, when the pH of the composition exceeds the upper limit, the polishing rate may decrease due to damage to the silica of the polishing particles, and when the pH of the composition is less than the lower limit, the chelating agent may bind to a proton (H⁺), thereby decreasing the metal ion chelating ability, and thus decreasing the polishing rate.

The CMP slurry composition may further include an oxidizing agent to induce oxidation of the polishing target film and improve the polishing rate.

According to an embodiment, the oxidizing agent may include at least one selected from the group consisting of hydrogen peroxide, urea hydrogen peroxide, urea, percarbonate, periodic acid, periodate, perchloric acid, perchlorate, perbromic acid, perbromate, perboric acid, perborate, potassium permanganate, sodium perborate, permanganic acid, permanganate, persulfate, bromate, chlorite, chlorate, chromate, dichromate, a chromium compound, iodate, iodine, ammonium peroxide, benzoyl peroxide, calcium peroxide, barium peroxide, sodium peroxide, dioxygenyl, ozone, ozonide, nitrate, hypochlorite, hypohalite, chromium trioxide, pyridinium chlorochromate, nitrous oxide, monopersulfate, dipersulfate, and sodium peroxide.

The CMP slurry composition may further include one or more of a surfactant and a polymer for dishing improvement in order to further improve the surface quality of the polishing target film.

The surfactant may serve to decrease a contact angle with the polishing target film to improve the uniformity of the polishing target film surface and promote the flowability of the composition. According to an embodiment, the surfactant may include at least one selected from the group consisting of an anionic surfactant, a cationic surfactant, and a nonionic surfactant.

The polymer for dishing improvement is a polymer that decreases a contact angle with the polishing target film to improve the uniformity of the polishing target film surface and reduce the dishing phenomenon. According to an embodiment, the polymer for dishing improvement may include at least one selected from the group consisting of a cationic polymer, an anionic polymer, a nonionic polymer, and a copolymer thereof.

The target film of the CMP slurry composition according to an embodiment of the present disclosure may be a metal film, the metal film may be a copper film, and the copper film may include at least one selected from the group consisting of a copper metal, copper nitride, copper oxide, and a copper alloy.

The polishing rate of the CMP slurry composition according to an embodiment of the present disclosure for the copper film may be 6,000 Å/min or more, more preferably 7,000 Å/min or more, even more preferably 8,000 Å/min or more, and most preferably 10,000 Å/min or more.

Hereinafter, the present disclosure will be described in more detail with reference to examples. The following examples are provided for the purpose of illustrating the present disclosure and are not intended to limit the scope of the present disclosure.

### EXAMPLES

### 1. Preparation of CMP Slurry Composition

### Example 1

0.1 wt % of the PMMA core-shell particles as the abrasive particles, 1.5 wt % of the chelating agent, 0.2 wt % of the corrosion inhibitor, and 1.0 wt % of the oxidizing agent were mixed and the pH adjuster was appropriately added to prepare a CMP slurry composition having a pH of 7.

### Example 2

A CMP slurry composition was prepared in the same manner as in Example 1, except that 0.5 wt % of PMMA core-shell particles was mixed.

### Example 3

A CMP slurry composition was prepared in the same manner as in Example 1, except that 1.0 wt % of PMMA core-shell particles was mixed.

### Example 4

A CMP slurry composition was prepared in the same manner as in Example 1, except that 1.0 wt % of PMMA core-shell particles was mixed and the pH of the composition was 5.

### Example 5

A CMP slurry composition was prepared in the same manner as in Example 1, except that 1.0 wt % of PMMA core-shell particles was mixed and the pH of the composition was 9.

### Comparative Example 1

A CMP slurry composition was prepared in the same manner as in Example 1, except that 0.1 wt % of silica particles was mixed as the abrasive particles.

### Comparative Example 2

A CMP slurry composition was prepared in the same manner as in Example 1, except that 1.0 wt % of silica particles was mixed as the abrasive particles.

### Comparative Example 3

A CMP slurry composition was prepared in the same manner as in Example 1, except that 0.1 wt % of PS core-shell particles was mixed as the abrasive particles.

### Comparative Example 4

A CMP slurry composition was prepared in the same manner as in Example 1, except that 1.0 wt % of PS core-shell particles was mixed as the abrasive particles.

### 2. Measurement of Polishing Rate and Surface State of Copper Film

The polishing rate was measured by polishing a copper plate using the CMP slurry compositions of the examples and the comparative examples under the polishing conditions shown in Table 1 below.

TABLE 1

| Evaluation equipment | SP-03/K1000 (KCT) | |
|---|---|---|
| Carrier rpm | 98 | |
| Platen rpm | 87 | |
| Wafer pressure | 3 | psi |
| R-Ring Pressure | 5.5 | psi |
| Slurry flow rate | 250 | ml/min |

| | |
|---|---|
| Polishing pad | IC 1000 |

In addition, the surface state of the polished copper film was observed using a scanning electron microscope (SEM) after polishing the copper film, and roughness and a degree of scratch occurrence were compared visually. The measured values for the polishing rate and the surface state after polishing are shown in Table 2 below.

TABLE 2

| | | | | | | Cu | Surface |
|---|---|---|---|---|---|---|---|
| | Abrasive | Chelating | Corrosion | | | polishing | state |
| | particles | agent | inhibitor | oxidizing agent | | rate | after |
| | wt % | wt % | wt % | wt % | pH | (Å/min) | polishing |
| Example 1 | PMMA | 1.5 wt % | 0.2 wt % | 1.0 wt % | 7 | 6,422 | ⊚ |
| | Coreshell | | | | | | |
| | 0.1 wt % | | | | | | |
| Example 2 | PMMA | 1.5 wt % | 0.2 wt % | 1.0 wt % | 7 | 8,119 | ⊚ |
| | Coreshell | | | | | | |
| | 0.5 wt % | | | | | | |
| Example 3 | PMMA | 1.5 wt % | 0.2 wt % | 1.0 wt % | 7 | 10,814 | ⊚ |
| | Coreshell | | | | | | |
| | 1.0 wt % | | | | | | |
| Example 4 | PMMA | 1.5 wt % | 0.2 wt % | 1.0 wt % | 5 | 7,970 | ⊚ |
| | Coreshell | | | | | | |
| | 1.0 wt % | | | | | | |
| Example 5 | PMMA | 1.5 wt % | 0.2 wt % | 1.0 wt % | 9 | 6,572 | ⊚ |
| | Coreshell | | | | | | |
| | 1.0 wt % | | | | | | |
| Comparative | Silica | 1.5 wt % | 0.2 wt % | 1.0 wt % | 7 | 6,760 | Δ |
| Example 1 | particles | | | | | | |
| | 0.1 wt % | | | | | | |
| Comparative | Silica | 1.5 wt % | 0.2 wt % | 1.0 wt % | 7 | 11,315 | X |
| Example 2 | particles | | | | | | |
| | 1.0 wt % | | | | | | |
| Comparative | PS | 1.5 wt % | 0.2 wt % | 1.0 wt % | 7 | 3,845 | ⊚ |
| Example 3 | Coreshell | | | | | | |
| | 0.1 wt % | | | | | | |
| Comparative | PS | 1.5 wt % | 0.2 wt % | 1.0 wt % | 7 | 4,918 | ⊚ |
| Example 4 | Coreshell | | | | | | |
| | 1.0 wt % | | | | | | |

(Surface state after polishing ⊚: Good, Δ: Average, X: Bad)

As may be confirmed through the results in Table 2, when comparing the cases where the “core-shell type particles” were used as the abrasive particles (Examples 1 to 5 and Comparative Examples 3 and 4) and the cases where the simple “silica particles” were used (Comparative Examples 1 and 2), it may be confirmed that, in the former case, the copper film surface state after polishing was good, whereas in the latter case, the copper film surface state after polishing was observed to be average or poor. In addition, when the “PMMA core-shell particles” and the “silica particles” were used as the abrasive particles (Examples 1 to 5 and Comparative Examples 1 and 2), it was confirmed that the polishing rate of the copper film was sufficiently secured at 6,000 Å/min or more, but when the “PS core-shell particles” were used (Comparative Examples 3 and 4), the polishing rate was not sufficiently secured.

Through this, it was confirmed that, when the core-shell structured particles are used as the abrasive particles, the quality of the copper film surface state may be improved due to the reduction of scratches, corrosion, and the like due to the high ductility of the organic polymer core, compared to the case where the simple inorganic particles are used. Particularly, it may be confirmed that, when a high-strength PMMA polymer is used as the core rather than a low-strength polymer such as PS, even for the same type of core-shell abrasive particles, the polishing rate of the copper film may be sufficiently secured at 6,000 Å/min or more within the range maintaining the polishing quality.

In addition, according to Examples 1 to 3, it may be found that the polishing rate gradually increases as the content of PMMA core-shell particles increases. However, referring to Comparative Examples 1 and 2, it may be found that, when the abrasive particles are added in a content exceeding a predetermined value, although the polishing rate increases, the quality of the surface state after polishing may rapidly deteriorate.

According to Examples 3 to 5, it may be found that the polishing rate is greatly improved as the pH of the composition approaches neutrality, from 6 to 8, and it may be found that the polishing rate is relatively reduced at pH values outside the above range. It is believed to be because, as the pH shifts toward acidity or alkalinity, the durability of the silica in the abrasive particles decreases or a bond is formed between the chelating agent and protons (H⁺), which reduces the polishing effect of each component of the composition.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents.

Therefore, other implementations, other embodiments, and equivalents to the claims are also within the scope of the following claims.

What is claimed is:

1. A chemical mechanical polishing (CMP) slurry composition comprising:
abrasive particles;
a chelating agent;
an oxidizing agent; and
a corrosion inhibitor,
wherein the abrasive particles are core-shell type particles in which a core is a polymethyl methacrylate (PMMA) polymer and a surface of the core is coated with inorganic oxide.

2. The CMP slurry composition of claim 1, wherein the inorganic oxide comprises at least one selected from the group consisting of silica, ceria, zirconia, alumina, titania, barium titania, germania, manganese, magnesia, and zeolite.

3. The CMP slurry composition of claim 1, wherein the abrasive particles are present in an amount of 0.01 wt % to 10 wt % in the CMP slurry composition.

4. The CMP slurry composition of claim 1, wherein the chelating agent comprises one or more of amino acid and organic acid.

5. The CMP slurry composition of claim 4, wherein the amino acid comprises at least one selected from the group consisting of glycine, arginine, lysine, histidine, aspartic acid, glutamic acid, asparagine, glutamine, tyrosine, serine, cysteine, threonine, alanine, β-alanine, proline, tryptophan, methionine, phenylalanine, valine, leucine, and isoleucine.

6. The CMP slurry composition of claim 1, wherein the corrosion inhibitor is an azole compound, and the azole compound comprises two or more nitrogen (N) atoms in a molecular structure.

7. The CMP slurry composition of claim 1, wherein the corrosion inhibitor comprises at least one selected from the group consisting of benzotriazole, 1,2,3-triazole, 1,2,4-triazole, tetrazole, imidazole, benzimidazole, pyrazole, pyrazine, pyrimidine, triazolopyridine, triazolopyrimidine, indazole, 5-methyl benzotriazole, 5-aminotetrazole, 1-alkyl-5-aminotetrazole, 5-hydroxy-tetrazole, 1-alkyl-5-hydroxy-tetrazole, tetrazole-5thiol, 1-H-benzotriazole-5-carboxylic acid, 1,2,3-triazole-3-carboxylic acid, and a combination thereof.

8. The CMP slurry composition of claim 1, further comprising:
a pH adjuster.

9. The CMP slurry composition of claim 8, wherein the pH adjuster comprises at least one selected from the group consisting of:
an acidic substance comprising at least one selected from the group consisting of hydrochloric acid, phosphoric acid, nitric acid, sulfuric acid, hydrofluoric acid, hydrobromic acid, iodic acid, formic acid, malonic acid, maleic acid, oxalic acid, acetic acid, adipic acid, citric acid, propionic acid, fumaric acid, lactic acid, salicylic acid, pimelic acid, benzoic acid, succinic acid, phthalic acid, butyric acid, glutaric acid, glutamic acid, glycolic acid, aspartic acid, tartaric acid, and a salt thereof; and
a basic substance comprising at least one selected from the group consisting of ammonia, ammonium methyl propanol (AMP), tetra methyl ammonium hydroxide (TMAH), ammonium hydroxide, potassium hydroxide, sodium hydroxide, magnesium hydroxide, rubidium hydroxide, cesium hydroxide, sodium bicarbonate, sodium carbonate, and imidazole.

10. The CMP slurry composition of claim 1, wherein a pH of the CMP slurry composition is 6 to 8.

11. The CMP slurry composition of claim 1, wherein the oxidizing agent comprises at least one selected from the group consisting of hydrogen peroxide, urea hydrogen peroxide, urea, percarbonate, periodic acid, periodate, perchloric acid, perchlorate, perbromic acid, perbromate, perboric acid, perborate, potassium permanganate, sodium perborate, permanganic acid, permanganate, persulfate, bromate, chlorite, chlorate, chromate, dichromate, a chromium compound, iodate, iodine, ammonium peroxide, benzoyl peroxide, calcium peroxide, barium peroxide, sodium peroxide, dioxygenyl, ozone, ozonide, nitrate, hypochlorite, hypohalite, chromium trioxide, pyridinium chlorochromate, nitrous oxide, monopersulfate, dipersulfate, and sodium peroxide.

12. The CMP slurry composition of claim 1, further comprising:
one or more of a surfactant and a polymer for dishing improvement.

13. The CMP slurry composition of claim 1, wherein
a polishing target film of the CMP slurry composition is a copper film, and
the copper film comprises at least one selected from the group consisting of a copper metal, copper nitride, copper oxide, and a copper alloy.
